(19) United States
(12) Patent Application Publication
(10) Pub. No.: US 2026/0129987 A1
(43) Pub. Date: May 7, 2026

(54) FLARE MITIGATING IMAGE SENSOR PACKAGES AND RELATED METHODS

(71) Applicant: SEMICONDUCTOR COMPONENTS INDUSTRIES, LLC, Scottsdale, AZ (US)

(72) Inventors: Swarnal BORTHAKUR, Boise, ID (US); Bryan ALMOND, Reading (GB)

(73) Assignee: SEMICONDUCTOR COMPONENTS INDUSTRIES, LLC, Scottsdale, AZ (US)

(21) Appl. No.: 18/938,830

(22) Filed: Nov. 6, 2024

(51) Int. Cl. H01L 27/146

(52) U.S. Cl. CPC H10F 39/804

(57) ABSTRACT

An image sensor package may include an optically transmissive cover including a first layer coupled to a largest planar surface of the optically transmissive cover; and a plurality of nanostructures in the first layer located adjacent a perimeter of the optically transmissive cover. The plurality of nanostructures may form a substantially solar-blind ultraviolet light pass filter.

### BACKGROUND

### 1. Technical Field

Aspects of this document relate generally to image sensor packages.

### 2. Background

Semiconductor packages have been developed that work to protect semiconductor die from shock or vibration. Various semiconductor packages also work to help facilitate electrical connections between pads on a semiconductor die and various electrical traces included in a circuit board or motherboard to which the semiconductor package is attached. Some semiconductor packages also are constructed to provide moisture protection for the semiconductor die. Image sensor packages also protect the die surface from particle or other sources of contamination that would hinder imaging performance.

### SUMMARY

An image sensor package may include an optically transmissive cover including a first layer coupled to a largest planar surface of the optically transmissive cover; and a plurality of nanostructures in the first layer located adjacent a perimeter of the optically transmissive cover. The plurality of nanostructures may form a substantially solar-blind ultraviolet light pass filter.

Implementation of an image sensor package may include one, all, or any of the following:

The pitch of the plurality of nanostructures and a size of each nanostructure of the plurality of nanostructures may be dimensioned to substantially prevent passage of visible light through the plurality of nanostructures.

The pitch of the plurality of nanostructures and a size of each nanostructure of the plurality of nanostructures may be dimensioned to substantially only allow passage of ultraviolet light through the plurality of nanostructures.

The plurality of nanostructures may include a grid including aluminum with holes in the grid filled with silicon dioxide.

The pitch of the aluminum grid may be 180 nanometers.

The holes may be square with sides each with a length of 67.5 nanometers.

The aluminum grid may be 150 nanometers thick.

The width of the plurality of nanostructures adjacent the perimeter of the optically transmissive cover may be between 200 microns to 500 microns.

The package may include an image sensor semiconductor die coupled to the optically transmissive cover where the largest planar surface faces the image sensor semiconductor die.

Implementations of an image sensor package may include an optically transmissive cover including a recess extending around a perimeter of a largest planar surface of the optically transmissive cover; and a plurality of nanostructures in the recess. The plurality of nanostructures may form a substantially solar-blind ultraviolet light pass filter.

The pitch of the plurality of nanostructures and a size of each nanostructure of the plurality of nanostructures may be dimensioned to substantially prevent passage of visible light through the plurality of nanostructures.

The pitch of the plurality of nanostructures and a size of each nanostructure of the plurality of nanostructures may be dimensioned to substantially allow only passage of ultraviolet light through the plurality of nanostructures.

The width of the plurality of nanostructures in the recess may be between 200 microns to 500 microns.

The package may include an image sensor semiconductor die coupled to the optically transmissive cover where the largest planar surface faces the image sensor semiconductor die.

Implementations of an image sensor package may include an optically transmissive cover including a plurality of nanostructures in a material of the optically transmissive cover. The plurality of nanostructures may form a substantially solar-blind ultraviolet light pass filter.

The pitch of the plurality of nanostructures and a size of each nanostructure of the plurality of nanostructures may be dimensioned to substantially prevent passage of visible light through the plurality of nanostructures.

The pitch of the plurality of nanostructures and a size of each nanostructure of the plurality of nanostructures may be dimensioned to substantially allow passage of only ultraviolet light through the plurality of nanostructures.

The width of the plurality of nanostructures in the material of the optically transmissive cover may be between 200 microns to 500 microns.

The package may include an image sensor semiconductor die coupled to the optically transmissive cover where the largest planar surface faces the image sensor semiconductor die.

Each of the plurality of nanostructures may extend into a thickness of the optically transmissive cover.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a top view of an implementation of an image sensor package;

FIG. 2 is a cross sectional detail view of the implementation of the image sensor package of FIG. 1 taken along sectional line A-A;

FIG. 3 is a top view of another implementation of an image sensor package;

FIG. 4 is a cross sectional detail view of the implementation of the image sensor package of FIG. 3 taken along sectional line B-B;

FIG. 5 is a cross sectional view of an implementation of another image sensor package;

FIG. 6 is a top view of an implementation of an image sensor package;

FIG. 7 is a top view of an implementation of an image sensor package;

FIG. 8 is a cross sectional view of an implementation of a optically transmissive cover with a layer of silicon dioxide formed thereon;

FIG. 9 is a cross sectional view of the optically transmissive cover of FIG. 8 following patterning and etching operations;

FIG. 10 is a cross sectional view of the optically transmissive cover of FIG. 9 following deposition and etching of aluminum and a singulation operation;

FIG. 11 is a cross sectional view of an implementation of a optically transmissive cover with a layer of aluminum formed thereon;

FIG. 12 is a cross sectional view of the optically transmissive cover of FIG. 11 following patterning and etching operations;

FIG. 13 is a cross sectional view of the optically transmissive cover of FIG. 12 following a silicon dioxide deposition operation and a singulation operation;

FIG. 14 is a cross sectional view of an implementation of a optically transmissive cover following etching of recesses thereon;

FIG. 15 is a cross sectional view of the optically transmissive cover of FIG. 14 following deposition of aluminum thereon;

FIG. 16 is a cross sectional view of the optically transmissive cover of FIG. 15 following patterning, etching, and singulation operations;

FIG. 17 is a cross sectional view of an optically transmissive cover following patterning and etching operations;

FIG. 18 is a cross sectional view of the optically transmissive cover of FIG. 17 following deposition of aluminum thereon; and

FIG. 19 is a cross sectional view of the optically transmissive cover of FIG. 18 following an etching and singulation operation.

### DESCRIPTION

This disclosure, its aspects and implementations, are not limited to the specific components, assembly procedures or method elements disclosed herein. Many additional components, assembly procedures and/or method elements known in the art consistent with the intended image sensor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such image sensor packages, and implementing components and methods, consistent with the intended operation and methods.

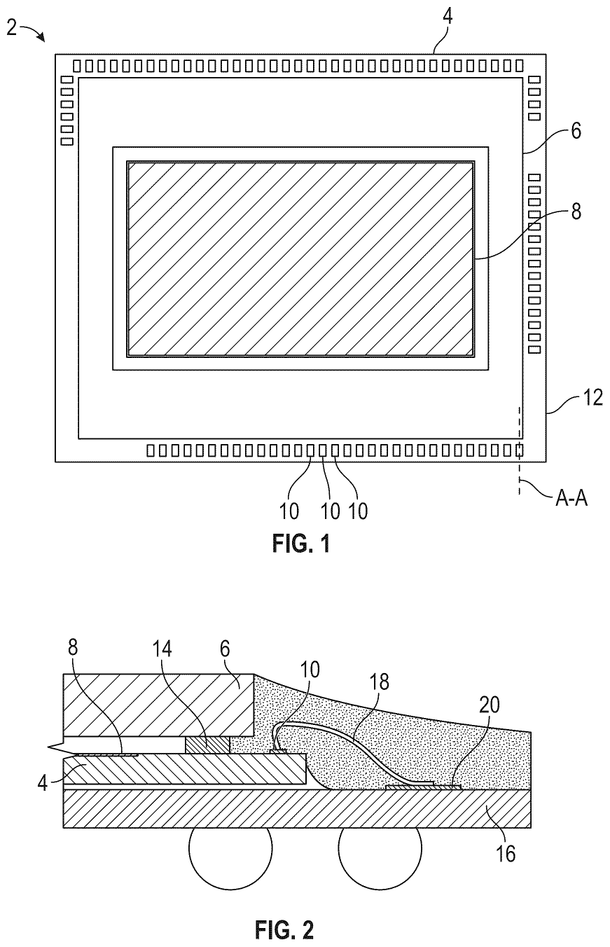

Referring to FIG. 1, an implementation of an image sensor package 2 is illustrated. As illustrated, the package 2 includes an image sensor die 4 over which an optically transmissive cover 6 has been coupled using an adhesive. The image sensor die 4 includes an active area 8 that includes a plurality of pixels and may, in various implementations, include a color filter array and various microlenses formed thereon. To allow for electrical connections to be formed between the image sensor die 4 and the image sensor package 2, a plurality of pads 10 are included at various locations along a perimeter 12 of the image sensor die 4. FIG. 2 is a detail cross sectional view of the image sensor package 2 along sectional line A-A. In this figure, the relationship between the image sensor die 4, the optically transmissive cover 6, the adhesive 14, the pad 10, and a substrate 16 of the package are illustrated. Here a bond wire 18 is used to form an electrical connection between the pad 10 and a corresponding pad 20 on the substrate 16. A mold compound has been applied to cover the wirebond and the joint between the image sensor die 4 and the optically transmissive cover 6.

As illustrated in FIG. 2, the active area 8 is exposed to various sources of reflected light from the structure of the package, including light reflections from vertical edge of the optically transmissive cover 6, light reflections from the adhesive 14, light reflections from the edges of the adhesive 14, and light reflections from the pad 10 or the wirebond 18. Because the optically transmissive cover 6 is free to transmit reflected light from these various structures of the package during operation, the reflected light appears in the images generated by the image sensor as flare.

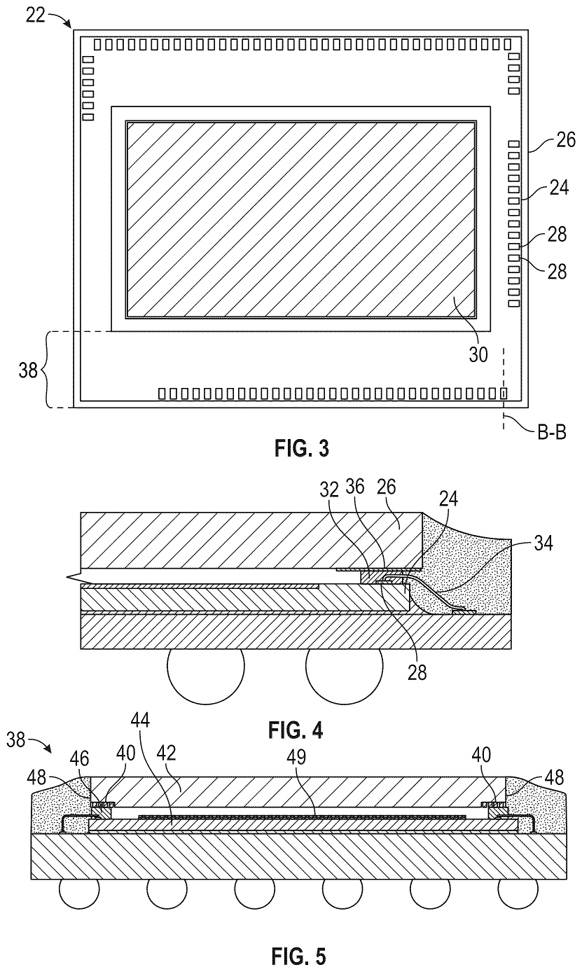

FIG. 3, a top view of another image sensor package implementation 22 is illustrated that similarly includes an image sensor die 24 coupled through an adhesive to optically transmissive cover 26. Pads 28 surround the perimeter of the image sensor die 24 that includes active area 30. As is visible in the detail cross sectional view of FIG. 4 taken along sectional line B-B, the perimeter of the optically transmissive cover 26 is larger than the perimeter of the image sensor die 24. Also, the pad 28 is located within the material of the adhesive 32 along with one end of the bond wire 34. Because of this, this image sensor package type is referred to as a wire-in-dam image sensor package. Between the adhesive 32 and the image sensor die 24 is a black material layer 36 referred to as “black-under-glass” that absorbs substantially all wavelengths of light that encounter it. The width of the black material layer 36 is set to provide a consistent gap around the perimeter of the active area 30 while covering the remaining surface of the optically transmissive cover 26 out to the edge of the cover.

This configuration substantially reduces the possibility of reflected light from the adhesive 32, the vertical edge of the optically transmissive cover 26, the pad 28, or bond wire 34 encountering the active area 30. The black material layer 36 is positioned to make such reflections into the active area 30 unlikely enough so that flare is unlikely to be observed during operation. The problem with this particular image sensor package implementation 26 arises with the adhesive 32. Because this design still employes a wire-in-dam structure, the adhesive 32 must be applied over the pads and bond wires while still in an uncured condition and then subsequently cured to form both a bond of the desired strength between the optically transmissive cover 26 and the image sensor die 24. If the curing is done using only thermal energy, then the black material layer 36 does not interfere with the curing process. However, where light with wavelengths in the ultraviolet portion of the electromagnetic spectrum is used to provide an initial cure or full cure of the adhesive material, the black material layer 36 makes achieving the desired cure difficult. This is because the ultraviolet light has great difficulty reaching the adhesive material and can achieve different amounts of cure at different bond pad locations. The result is that corrosion of the wirebonds and bond wires has been observed due to ionic migration in the uncured material. Also breaking of/delamination of the bond between the image sensor die and the optically transmissive cover 26 has been observed in various image sensor package implementations.

In this document, the use of nanostructures instead of a black material layer in a wire-in-dam image sensor package design is disclosed. These nanostructures contain dimensions that measure in the nanometers (hence the name) and function, because of their size, to substantially block wavelengths of light except for those with small enough wavelengths to pass through the nanostructures. Thus, the particular structures disclosed herein can act as a solar-blind ultraviolet light pass filter, meaning that all of the wavelengths of light from earth's sun except those in the ultraviolet range are absorbed by the nanostructures. Thus, only ultraviolet light is allowed to pass through the filter and solar radiation is entirely or substantially entirely absorbed.

Referring to FIG. 5, an implementation of an image sensor package 38 is illustrated that includes nanostructures 40 formed in the material of its optically transmissive cover 42. Like the previous implementations, the optically transmissive cover 42 is attached to image sensor die 44 using adhesive 46 and this package is a wire-in-dam system like the implementation illustrated in FIG. 4. The nanostructures 40 are disposed around the perimeter 48 of the optically transmissive cover 42 and, in this implementation, extend all the way out to the edge of the optically transmissive cover 42. The nanostructures 40 are dimensioned with size dimensions and with structural relationships that create a structure that forms a solar-blind ultraviolet light pass filter. The particular general shape of the nanostructures is that of a grid of intersecting lines of nanometer sized features that forms a set of openings therethrough. The size of the openings of the grid serves to prevent wavelengths of light longer than ultraviolet light wavelengths from passing through the openings, thus forming an ultraviolet light only pass filter. Examples of three dimensional grid nanostructures that could be employed in various implementations can be found in the paper to Li et al, entitled “Solar-blind deep-UV band-bass filter (250-350 nm) consisting of a metal nano-grid fabricated by nanoimprint lithography,” Optics Express, V. 18, No. 2, p. 931-937 (6 Jan 2010), the disclosure of which is hereby incorporated entirely herein by reference.

As illustrated in FIG. 4, the optically transmissive cover 42 is sized to be the same size as the image sensor die 44. However, in other implementations, the optically transmissive cover 42 could be larger than or smaller than the image sensor die 44. Because ultraviolet light can pass freely through the nanostructures 40, issues with overhang of a black material layer can be avoided entirely, as a uniform amount of ultraviolet light can penetrate the adhesive 46 and induce the desired curing reactions. However, because in this implementation the nanostructures 40 prevent transmission of any other wavelengths of light other than ultraviolet and higher energy (or lower wavelength) through them, the ability for the pixels in the active area 49 to detect other wavelengths of visible light reflecting from the adhesive, edge of the optically transmissive cover, pads, or bond wires is substantially reduced. Thus the optical effect of the nanostructures is similar to the black material layer in preventing flare in images generated by the pixels. This result, however, would not apply if the pixels were designed to detect ultraviolet light, as then the nanostructures would have little effect on reducing flare. However, for other image sensor die types designed to detect infrared or visible light, the nanostructures would prevent light reflections from entering the pixel array in those wavelengths.

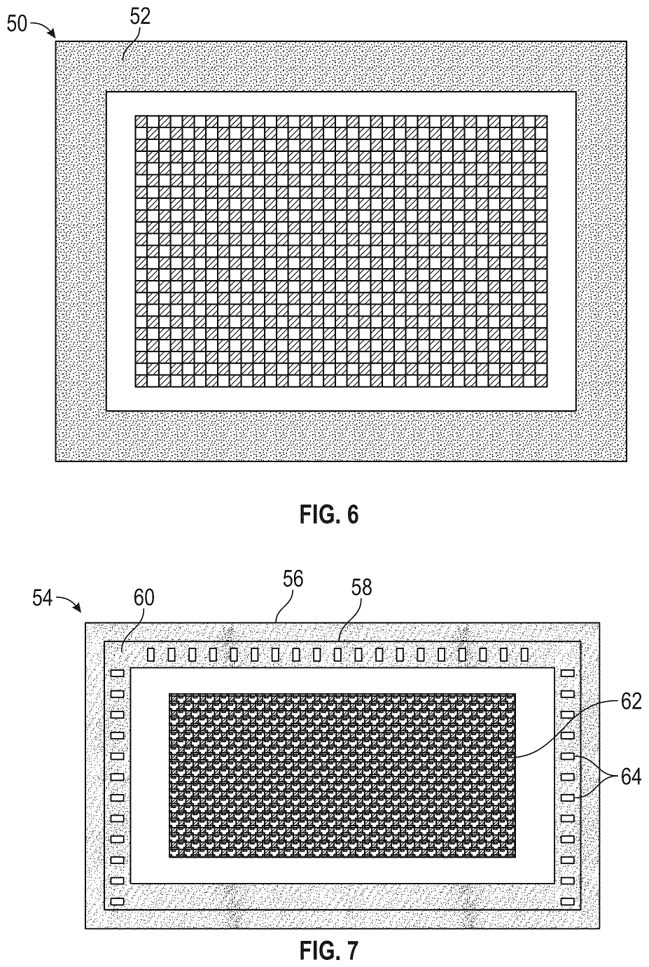

The nanostructures illustrated in FIG. 5 are not shown to scale for the purposes of illustration as they would be otherwise not discernible at the scale of structures illustrated in FIG. 5. In FIG. 6, a top down view of an image sensor package 50 is illustrated that shows the location of the nanostructures 52 arranged around the perimeter of the optically conductive glass layer. Here the nanostructures are represented for the purposes of illustration using a stipple pattern which reflects that their actual structure cannot be discerned at this scale. In this implementation, the structure of the nanostructures 52 is that of a grid pattern. However, in some implementations, where the spacing between individual nanostructures can be controlled, a random or semi-random pattern like a stipple pattern could be employed for the nanostructures to prevent substantially all of the visible light wave lengths and infrared wavelengths from passing through. In various image sensor package implementations, 100% prevention of all visible and infrared light wavelengths from passing through the nanostructures is not needed to achieve the desired reduction in flare. In some implementations, 99% prevention is sufficient. In other implementations, 95% prevention is sufficient. In yet other implementations, 90% prevention is sufficient. In yet other implementations, 85% prevention is sufficient. In yet other implementations, 80% prevention is sufficient. Because of this ability to achieve the desired reduction in flare without 100% prevention, the need to have the structure of the nanostructures be perfectly or even substantially perfectly uniform may be reduced. Thus stipple patterns or structures with various amounts/levels of defects could achieve these desired levels of prevention. This may be helpful in various implementations because of the difficulty in forming the nanostructures and/or the cost involved in forming the nanostructures with very low defect densities either because of the processing conditions (such as microcontamination issues caused by processing in a class 10000 or class 1000 facility rather than a class 1 cleanroom facility) or the process capability of the nanostructure forming equipment and/or processes being utilized (less capable being used to reduce costs, for example).

FIG. 7 is a top view of another semiconductor package implementation 54 where the optically transmissive cover 56 is larger than the image sensor die 58. The position of the nanostructures 60 is also illustrated relative to the pixel array 62 which cover all of the bond pads 64 entirely, thus helping prevent flare and other reflections by acting as a solar-blind ultraviolet light pass filter. A wide variety of configurations of various nanostructures on optically transmissive covers may be constructed using the principles disclosed in this document.

Various semiconductor package implementations and various methods of forming the same will be discussed subsequently in this document. In some of these, the resulting structure is the same or similar, but in others, the resulting structure is different. However, all of the different image sensor package structures can function/create a substantially solar-blind ultraviolet light pass filter. Various methods of forming image sensor packages will be discussed subsequently herein. While the use of silicon dioxide as the material of first layer is disclosed, other material types could be used that meet index of refraction requirements for the particular image sensor design. Also, while the use of aluminum as the material of the nanostructures is disclosed in the following examples, a wide variety of other materials could be employed, including, by non-limiting example, aluminum alloys, copper, copper alloys, silver, silver alloys, gold, gold alloys, carbon, tungsten, titanium, any combination thereof, or any other material capable of absorbing light radiation.

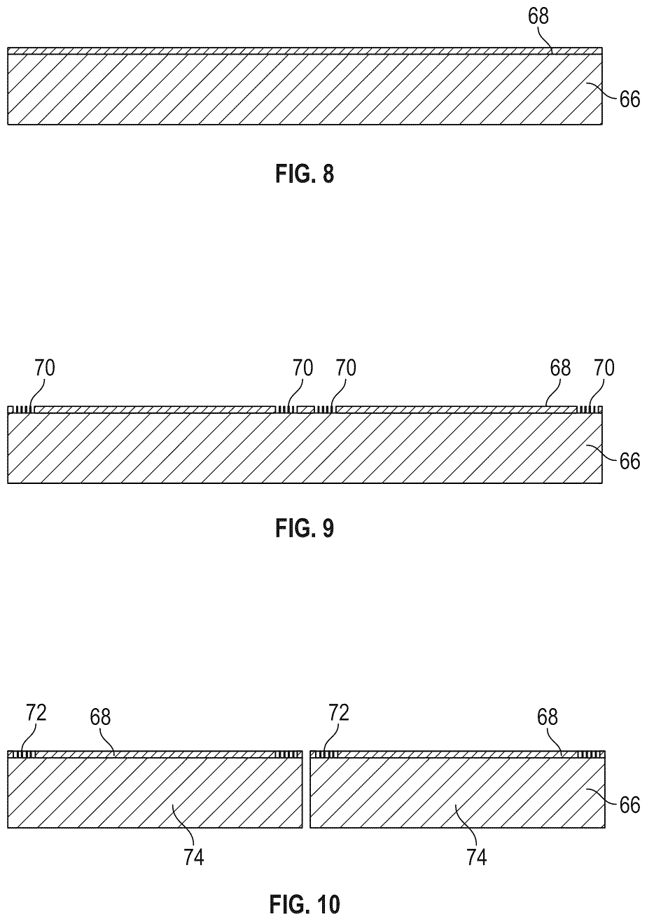

Referring to FIG. 8, an implementation of an optically transmissive panel 66 is illustrated following formation of a layer of silicon dioxide 68 thereon. The layer of silicon dioxide may be formed using any of a wide variety of methods including, by non-limiting example, chemical vapor deposition, sputtering, atomic layer deposition, wet oxide growth, or any other method of forming a silicon dioxide layer on the material of the optically transmissive panel. While the use of silicon dioxide is disclosed in this method implementation, other materials could potentially be used that would meet index of refraction requirement for the particular image sensor and wavelength(s) of light involved and/or match the index of refraction of the particular material of the optically transmissive panel itself. Because the material of the optically transmissive panel 66 is often a type of glass that includes all or a substantial portion of silicon dioxide, adding an additional layer of silicon dioxide may have a negligible effect on the overall index of refraction of the optically transmissive panel 66.

FIG. 9 is a cross sectional view of the optically transmissive panel 66 following patterning and etching of a set of openings 70 corresponding with the dimensions of the eventual nanostructures into the silicon dioxide layer 68. These openings 70 are sized and positioned as the negative image of the nanostructures that will be formed therein. While in FIG. 9 the set of openings 70 is illustrated as extending through an entire thickness of the silicon dioxide layer 68, this may not be the case in various implementations where the openings may extend only partially into the thickness.

Referring to FIG. 10, the optically transmissive panel 66 is illustrated following application of a layer of aluminum over the layer of silicon dioxide 68 which filled the openings 70 and created nanostructures 72 of aluminum in the silicon dioxide layer 68. The layer of aluminum may be formed using various methods including, by non-limiting example, sputtering, chemical vapor deposition, atomic layer deposition, or any other method of applying aluminum to the silicon dioxide layer. Following application of the aluminum layer, a patterned layer may be formed over the locations between the areas of nanostructures leaving them exposed to an etching/removal process that removes the aluminum layer from over the where the pixel array will be located and over the nanostructures 72 so that ultraviolet light can pass through the nanostructures 72. In some implementations, no patterned layer may be used, but a simple blanket etching, chemical mechanical planarization, or grinding operation may be used to remove the remaining aluminum leaving the nanostructures 72. Following the etching/removal process, a singulating process is then carried out that separates the optically transmissive panel 66 into optically transmissive covers 74. While in the method implementation disclosed in FIGS. 8-10 the processing is illustrated on the panel scale, in other implementations, the processing operations could be carried out on just the optically transmissive cover level in various method implementations.

In the optically transmissive cover implementations 74 illustrated in FIG. 10, the various nanostructures 72 that extend into the silicon dioxide layer are no longer connected through remaining aluminum that was formed onto the silicon dioxide layer originally.

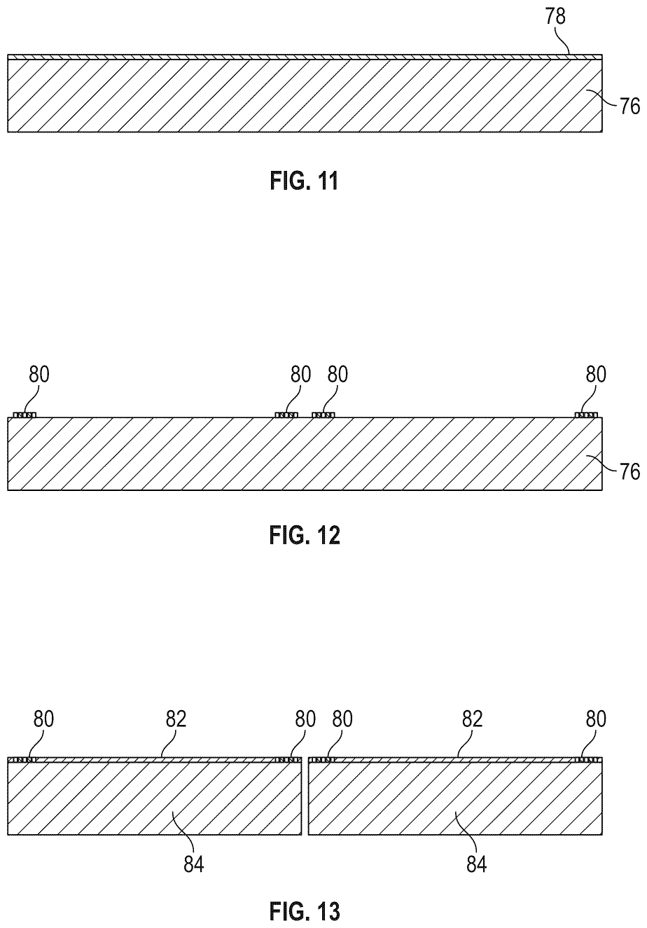

Referring to FIG. 11, another implementation of an optically transmissive panel 76 is illustrated following formation of an aluminum layer 78 thereon. This aluminum layer 78 may be formed using any of the methods disclosed in this document. Following formation of the aluminum layer 78, a patterned layer is formed over the aluminum layer 78 and then an etching process is used to etch all of the aluminum layer 78 except for nanostructures 80 around the perimeter of the optically transmissive covers included in the optically transmissive panel 76 (see FIG. 12). The patterning of the patterned layer may be formed using, by non-limiting example, lithography, nanoimprint lithography, a spraying process to create a dithered pattern, a resist etch back lithography process, or any other patterning process capable of producing the nanoscale features of the nanostructures 80.

Referring to FIG. 13, the optically transmissive panel is illustrated following formation of a silicon dioxide layer 82 over the nanostructures 80. In some method implementations, a planarizing operation may be carried out to level the silicon dioxide layer 82 over the nanostructures 80. In other implementations, however, no planarizing may be used, particularly where the nanostructures are only in the hundreds of nanometers thick/tall. FIG. 13 illustrates how a singulation operation has been carried out to separate the optically transmissive panel into optically transmissive covers 84. This particular method implementation creates a very similarly structured optically transmissive cover 84 as the ones illustrated in FIG. 10.

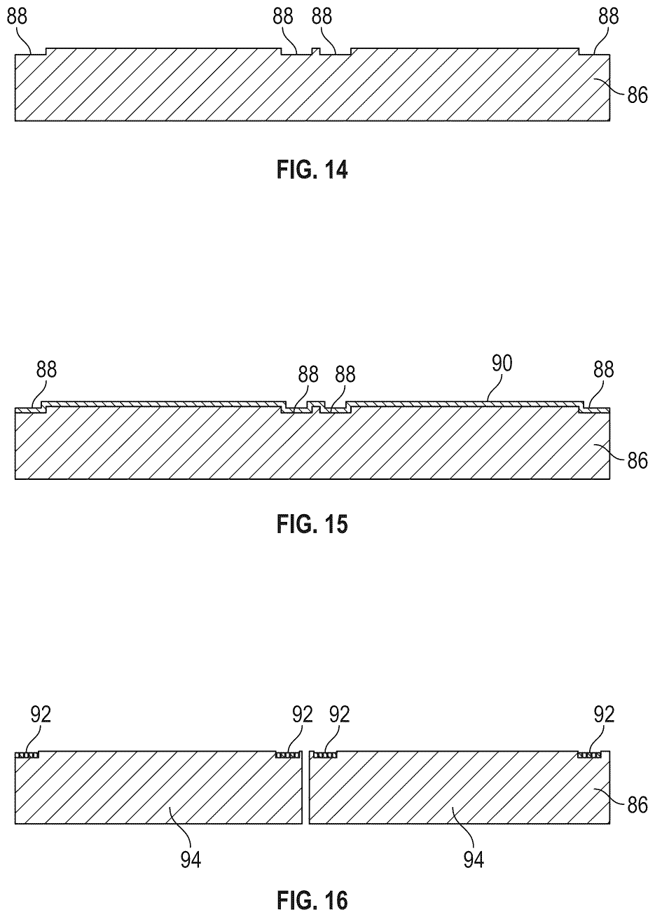

FIG. 14 illustrates another optically transmissive panel implementation 86 which may be made of any material disclosed herein following formation of a patterned layer thereon and an etching process that forms recesses 88 into the material of the optically transmissive panel 86. The etching process used may be any compatible with the material of the optically transmissive panel including dry etching or wet etching. Referring to FIG. 15, the optically transmissive panel 86 is illustrated after a layer of aluminum 90 has been deposited over the surface of the optically transmissive panel 86 and into the recesses 88. This aluminum layer 90 may be deposited using any method of deposition disclosed herein.

Following formation of the aluminum layer 90, a patterned layer is formed over the aluminum layer that contains spacings that allow for etching of openings in the aluminum layer 90 in the recesses 88 to form nanostructures 92 (see FIG. 16). The etching of the openings to form the nanostructures 92 may result in the removal of the remaining aluminum layer in some method implementations. In other implementations, however, a separate etching process may be used to remove the remaining aluminum layer over the areas of the optically transmissive panel 86 where the pixel array will be located. In such method implementations, a separate patterned layer may be formed over the nanostructures 92 to protect them during the aluminum etching process followed by a removal operation of the patterned layer. In some method implementations, a layer of silicon dioxide may be formed over the nanostructures and optically transmissive panel 86 to provide a covering over the nanostructures 92 and/or stabilize them during subsequent processing. As illustrated in FIG. 16, a singulating process is then carried out that separate the optically transmissive panel into optically transmissive covers 94.

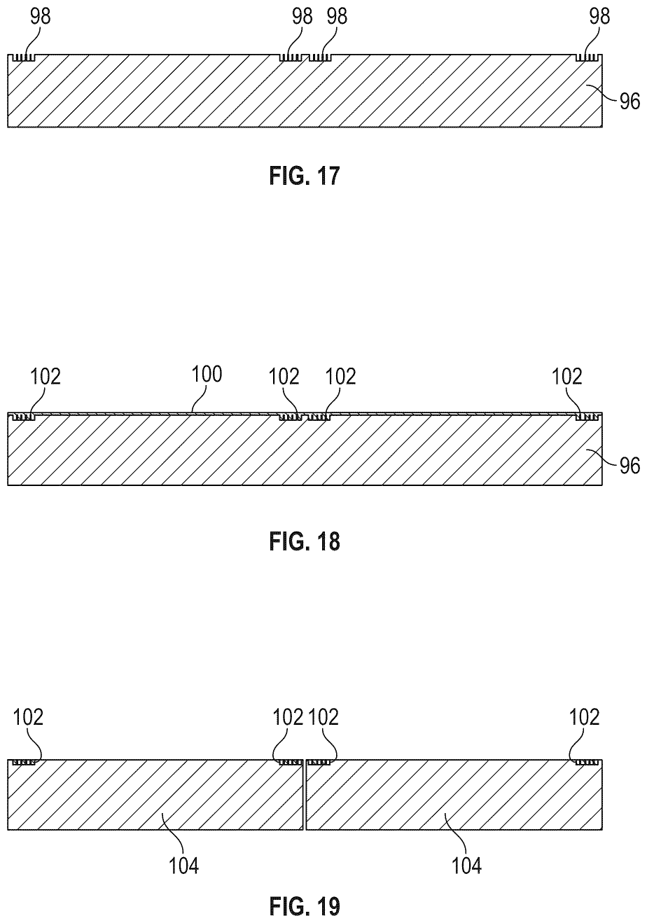

Referring to FIG. 17, an implementation of an optically transmissive panel 96 is illustrated following formation of a patterned layer thereon that is then used in an etching process to create sets of openings 98 into the material of the optically transmissive panel that form the negative pattern of a set of nanostructures. In FIG. 17, the patterned layer has been removed following the etching of the sets of openings 98. The etching of the sets of openings 98 may be carried out using any etching method compatible with the material of the optically transmissive panel 96. FIG. 18 illustrates the optically transmissive panel 96 following deposition of an aluminum layer 100 thereon into the sets of openings 98 to form nanostructures 102. The aluminum layer 100 may be formed using any method of depositing aluminum disclosed herein.

Following deposition of the aluminum layer 100, the material of the aluminum layer that is present over the areas of the optically transmissive panel 96 that will eventually cover the pixel array of an image sensor die is then removed (see FIG. 19). In some implementations, a blanket etching process (wet or dry) may be employed. In other implementations, a chemical mechanical planarization process may be employed. In yet other implementations a grinding and/or lapping and/or polishing process may be employed. In yet other implementations, to preserve the structure of the nanostructures 102, an initial pattering process to form a patterned layer over the nanostructures prior to bulk etching of the remaining aluminum film may be carried out followed by removal of the patterned layer and etching of the aluminum film that connects the various nanostructures 102 together. The particular method may be determined by the thickness of the aluminum layer 100 used.

FIG. 19 also illustrates how after the etching of the aluminum layer, a singulation process is carried out to form optically transmissive covers 104. The resulting structure of the optically transmissive cover 104 does not include an additional silicon dioxide layer as the nanostructures 102 are formed directly into the material of the optically transmissive covers 104 themselves.

A wide variety of nanostructure types and dimensions could be employed in various implementations, including any disclosed in this document. In a particular implementation, the structure of the nanostructures takes the form of a grid. In a particular implementation, the grid has a pitch of about 180 nanometers and includes holes/openings therethrough. The holes are square with side length of about 67.5 nanometers. The particular dimensions of the nanostructure are a function of the wavelength(s) of the light that the nanostructures are intended to pass and to exclude.

In particular implementations, the width of the nanostructures into an optically transmissive cover around the perimeter of the same may be between about 200 microns to about 500 microns. In various implementations, the nanostructures form a continuous band of this range of widths around the perimeter of the optically transmissive cover. In some implementations, one or more gaps in the band may be included where the nanostructures are not needed. In other implementations, the width of the nanostructures may vary on one side, two sides, three sides, or all four sides of the optically transmissive cover.

In places where the description above refers to particular implementations of image sensor packages and implementing components, sub-components, methods and sub-methods, it should be readily apparent that a number of modifications may be made without departing from the spirit thereof and that these implementations, implementing components, sub-components, methods and sub-methods may be applied to other image sensor packages.

What is claimed is:

1. An image sensor package comprising:
an optically transmissive cover comprising:
a first layer coupled to a largest planar surface of the optically transmissive cover; and
a plurality of nanostructures in the first layer located adjacent a perimeter of the optically transmissive cover;
wherein the plurality of nanostructures form a substantially solar-blind ultraviolet light pass filter.

2. The package of claim 1, wherein a pitch of the plurality of nanostructures and a size of each nanostructure of the plurality of nanostructures is dimensioned to substantially prevent passage of visible light through the plurality of nanostructures.

3. The package of claim 1, wherein a pitch of the plurality of nanostructures and a size of each nanostructure of the plurality of nanostructures is dimensioned to substantially only allow passage of ultraviolet light through the plurality of nanostructures.

4. The package of claim 1, wherein the plurality of nanostructures comprise a grid comprising aluminum with holes in the grid filled with silicon dioxide.

5. The package of claim 4, wherein a pitch of the aluminum grid is 180 nanometers.

6. The package of claim 4, wherein the holes are square with sides each with a length of 67.5 nanometers.

7. The package of claim 4, wherein the aluminum grid is 150 nanometers thick.

8. The package of claim 1, wherein a width of the plurality of nanostructures adjacent the perimeter of the optically transmissive cover is between 200 microns to 500 microns.

9. The package of claim 1, further comprising an image sensor semiconductor die coupled to the optically transmissive cover where the largest planar surface faces the image sensor semiconductor die.

10. An image sensor package comprising:
an optically transmissive cover comprising:
a recess extending around a perimeter of a largest planar surface of the optically transmissive cover; and
a plurality of nanostructures in the recess;
wherein the plurality of nanostructures form a substantially solar-blind ultraviolet light pass filter.

11. The package of claim 10, wherein a pitch of the plurality of nanostructures and a size of each nanostructure of the plurality of nanostructures is dimensioned to substantially prevent passage of visible light through the plurality of nanostructures.

12. The package of claim 10, wherein a pitch of the plurality of nanostructures and a size of each nanostructure of the plurality of nanostructures is dimensioned to substantially allow only passage of ultraviolet light through the plurality of nanostructures.

13. The package of claim 10, wherein a width of the plurality of nanostructures in the recess is between 200 microns to 500 microns.

14. The package of claim 10, further comprising an image sensor semiconductor die coupled to the optically transmissive cover where the largest planar surface faces the image sensor semiconductor die.

15. An image sensor package comprising:
an optically transmissive cover comprising a plurality of nanostructures in a material of the optically transmissive cover;
wherein the plurality of nanostructures form a substantially solar-blind ultraviolet light pass filter.

16. The package of claim 15, wherein a pitch of the plurality of nanostructures and a size of each nanostructure of the plurality of nanostructures is dimensioned to substantially prevent passage of visible light through the plurality of nanostructures.

17. The package of claim 15, wherein a pitch of the plurality of nanostructures and a size of each nanostructure of the plurality of nanostructures is dimensioned to substantially allow passage of only ultraviolet light through the plurality of nanostructures.

18. The package of claim 15, wherein a width of the plurality of nanostructures in the material of the optically transmissive cover is between 200 microns to 500 microns.

19. The package of claim 15, further comprising an image sensor semiconductor die coupled to the optically transmissive cover where the largest planar surface faces the image sensor semiconductor die.

20. The package of claim 15, wherein each of the plurality of nanostructures extends into a thickness of the optically transmissive cover.
